(19) United States
(12) Patent Application Publication
(10) Pub. No.: US 2010/0188112 A1
(43) Pub. Date: Jul. 29, 2010

(54) INSPECTION SOCKET

(75) Inventor: Takuto Yoshida, Tokyo (JP)

Correspondence Address: MORGAN LEWIS & BOCKIUS LLP, 1111 PENNSYLVANIA AVENUE NW, WASHINGTON, DC, 20004, US

(73) Assignee: Yokowo Co., Ltd.

(21) Appl. No.: 12/695,714

(22) Filed: Jan. 28, 2010

(30) Foreign Application Priority Data
Jan. 29, 2009 (JP) P.2009-017916

(51) Int. Cl. G01R 31/02

(52) U.S. Cl. 324/755

(57) ABSTRACT

An inspection socket connects electrode terminals of an object to be inspected to wirings of a wiring board. The inspection socket includes: a metal block formed with first holes; contact probes provided in the first holes and including at least a contact probe for RF signals, the contact probes provided with plungers capable of moving in an axial direction at distal ends of the contact probes; and an insulating board securing the contact probes and formed with second holes through which the plungers are passed, the insulating board provided with a GND member around the contact probe for RF signals.

### BACKGROUND OF THE INVENTION

The present invention relates to an inspection socket for reliably bringing electrode terminals of an object to be inspected into contact with a wiring board which is connected to an inspection device, on occasion of inspecting a monolithic IC, a hybrid IC of an LSI (a large scale integrated circuit), or a module component obtained by combining discrete components such as a plurality of ICs and LCRs into hybrid thereby to realize desired functions (hereinafter, all of them are referred to simply as an IC or an object to be inspected). More particularly, the invention relates to the inspection socket which can reliably connect the object to be inspected for high frequency and high speed (high frequency in analogue form is referred to as the high frequency, while very short pulse width and short pulse interval in digital form are referred to as the high speed, both of which are hereinafter referred to as an RF) so that signals can be reliably transmitted, even when an IC having a narrow pitch where intervals between the electrode terminals are very narrow as small as 0.4 mm is inspected.

In the IC which has been high integrated and high functioned in recent years, it is necessary to inspect its performance, before the IC is actually incorporated into a circuit. In case of inspecting such IC or the like, the electrode terminals of the IC or the like must be reliably brought into contact with wiring terminals of a wiring board on which wirings connected to an inspection device are formed, without soldering. For this purpose, as shown in FIG. 5A, for example, an inspection socket 1 is interposed between a wiring board 2 and an IC 3 thereby to conduct an inspection. FIG. 5B is an enlarged explanatory view showing a part including a contact probe 128 for RF signals.

In an example as shown in FIGS. 5A and 53, this inspection socket 1 is so constructed that contact probes 12 are inserted into insertion holes which are provided in a metal block 11, and insulating boards 13 called as pressure plates are fixed to both upper and lower surfaces of the metal block 11 with screws, which are not shown, so that the contact probes 12 may not escape from the metal block 11. The contact probes 12 includes contact probes 12S for RF signals, contact probes 12P for low frequency signals or power supply, contact probes 120D for grounding and so on. These contact probes 12 are provided so as to correspond to a power supply terminal of the IC 3 or the like (refer to JP-A-2004-325305, for example).

Along with recent tendency that the IC or the like has become high integrated and small-sized, a pitch of electrode terminals 31 of the IC 3 or the like has become very small to be about 0.4 mm. The contact probe 12P for high frequency or power supply may be inserted interposing an insulating tube 19 so as not to come into contact with the metal block 11. On the other hand, the contact probe 123 for RF signals must be formed in a coaxial structure having its impedance matched. Otherwise, the signals are attenuated, and accurate inspection cannot be performed. Specifically, when the RF signal of more than 1 GHz is transmitted through a small lead such as the contact probe, transmission of the signal may be obstructed by its reactance component or the signal may be reflected, and such bad influence cannot be disregarded. For example, even in case where a short contact probe having a length of about 2 mm is used for the purpose of reducing its inductance component, it would be difficult to reduce its reactance component to less than 1 nH. The probe having the reactance component of 1 nH, for example, will make an impedance of 63Ω at 10 GHz.

In order to solve the above described problem, it is necessary to satisfy the following formula (1) between an outer diameter d of an internal conductor, an inner diameter ID of an external conductor, and a dielectric constant ∈r of dielectric substance between the internal conductor and the external conductor thereby to obtain a specified impedance Zo, for the purpose of obtaining the coaxial structure and matching of the impedance. Accordingly, the dielectric constant of the dielectric substance must be made smaller, for further making a diameter of an insertion hole 11a smaller, even though the pitch between the electrode terminals becomes so small that the outer diameter of the contact probe as the internal conductor may come to a limit of about 0.15 mm. For this reason, in the example as shown in FIGS. 5A and 5B, the dielectric constant ∈r is made as small as 1, by holding the contact probe 12S for RF signals in a hollow space in the insertion hole 11a. In this manner, an escape of the contact probe 12 is prevented by the insulating board 13, and the contact probe 12S for RF signals is held in the hollow space at a center of the insertion hole 11a.

$$\begin{matrix}[ Formula 1 ] & \\ Zo = \frac{60}{\sqrt{ɛ r}} {log}_{e} \frac{D}{d} & ( 1 )\end{matrix}$$

As described above, along with the tendency that the object to be inspected becomes high frequency and high speed, there has been employed such a structure of the inspection socket that the contact probes are held in the through holes in the metal block to obtain the coaxial structure. However, even with this coaxial structure, there has occurred such a problem that characteristics of an insertion loss, reflection loss, cross talk and so on are deteriorated in a high frequency and high speed zone of more than 10 GHz. Specifically, although the insulating board 13 which is generally called as the pressure plate for holding the contact probe is very thin to be about 0.6 mm, the external conductor is not provided in the insulating board 13, and the coaxial structure cannot be formed, and hence, the RF performance is deteriorated. On the other hand, in the related art disclosed in JP-A-2004-325305, it has been considered that the metal block is formed in a three layered structure, and the contact probe is held in a recess formed in a metal lid at an outer face side, interposing an insulating spacer. Alternatively, it has been also considered that the contact probe 12 is secured by a GND board which is formed of an insulating board such as glass epoxy and provided with through holes at an interval of about 1 mm, and veers formed in the through holes. However, in the structure for fixing the contact probe in the recess in the metal lid, interposing the insulating spacer, it is very difficult in itself to form the insulating spacer which is extremely small, and assembling work is also very difficult. Therefore, this structure is hardly realized, in case where the pitch is less than 0.7 mm. In the structure of using the GND board too, it is very difficult to produce the GND board, and there is such anxiety that the veers may get in touch with the contact probes, depending on positions of the veers.

### SUMMARY

It is therefore an object of the invention to provide an inspection socket which can improve isolation characteristic, without causing disturbance of impedance in high frequency and high speed zone, even in case of inspecting an IC or the like having terminals for RF signals and provided with electrode terminals at a very narrow pitch of intervals between them in recent years.

In order to achieve the object, according to the invention, there is provided an inspection socket, connecting electrode terminals of an object to be inspected to wirings of a wiring board, the inspection socket comprising:

a metal block formed with first holes;

contact probes provided in the first holes and including at least a contact probe for RF signals, the contact probes provided with plungers capable of moving in an axial direction at distal ends of the contact probes; and

an insulating board securing the contact probes and formed with second holes through which the plungers are passed, the insulating board provided with a GND member around the contact probe for RF signals.

The GND member may be defined by a third hole formed in the insulating board and a metallic coating formed on an inner face of the third hole.

The GND member may include a metallic material being in contact with the metal block.

The contact probes may be arranged in a first direction and a second direction perpendicular to the first direction. The GND member may include a GND post arranged between the contact probe for RF signals and another contact probe which is diagonally adjacent to the contact probe for RF signals.

The contact probes may be arranged in a first direction and a second direction perpendicular to the first direction. The GND member may include a GND wall arranged between the contact probe for RF signals and another contact probe which is adjacent to the contact probe for RF signals in the first direction.

The contact probes may be arranged in a first direction and a second direction perpendicular to the first direction. The GND member may include GND posts and a GND wall. The GND posts may be arranged in the first direction and are arranged between the contact probe for RF signals and another contact probes which are diagonally adjacent to the contact probe for RF signals. The GND wall may interconnect the GND posts.

### BRIEF DESCRIPTION OF THE DRAWINGS

FIG. 1A is a plan view for illustrating an inspection socket in an embodiment according to the invention, FIG. 1B is a sectional view taken along a line B-B (a line alternately interconnecting contact probes and GND posts) in FIG. 1A, and FIG. 1C is a sectional view showing an example of the contact probe.

FIG. 2 is an explanatory view in section partly including a perspective view, showing an area including the GND posts and an area for fixing the contact probes in an insulating board as shown in FIGS. 1A and 18.

FIGS. 3A, 3B and 3C are explanatory views showing examples in which GND walls are formed, in another embodiment of the invention.

FIGS. 4A, 4B, 4C and 4D are charts showing results of simulations carried out in the arrangement of contact probes for RF signals and contact probes for grounding as shown in FIG. 1A, in which characteristics of insertion loss, reflection loss, near end cross talk, and far end cross talk are simulated and compared between a structure A of the invention in which the GND posts are erected at positions as shown in FIG. 1A, and a related-art structure B in which the GND posts are not erected, although arrangement of the contact probes is the same.

FIGS. 5A and 5B are explanatory views showing an example of a related-art structure of an inspection socket.

### DETAILED DESCRIPTION OF EMBODIMENTS

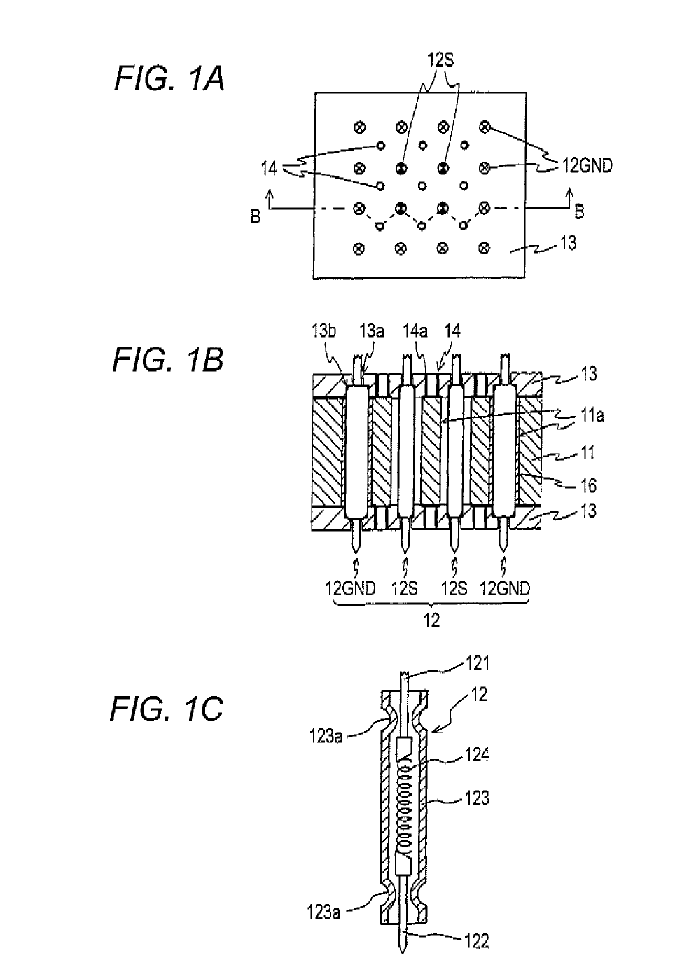

Now, the inspection socket according to the invention will be described, referring to FIGS. 1A to 1C.

The inspection socket according to the invention connects electrode terminals of an object to be inspected such as an IC to wirings of a wiring board. Contact probes 12 including at least contact probes 12S for RF signals are contained in insertion holes 11a which are formed in a metal block 11 in a plate-like shape (In the example as shown in FIGS. 1A and 1B, only the contact probes 12S for RF signals and the contact probe 12GND for grounding are shown, but actually, contact probes for low frequency signals and contact probes for power supply are also provided), and secured by insulating boards (pressure plates) 13 so as not to escape from the metal block 11. Each of the contact probes 12 is provided with plungers 121, 122 which can move in an axial direction, at distal ends thereof. Each of the insulating boards 13 is provided with through holes 13a through which the plungers can be freely passed and recesses 13b for securing shoulder parts of the contact probes 12. In the invention, GND posts 14 or GND walls are formed in the insulating board 13 at any positions surrounding at least the contact probes 12S for RF signals out of the contact probes 12.

The metal block 11 holds the contact probes 12 for signal terminals, for power supply terminals or for grounding terminals and so on to be brought into contact with electrode terminals of the object to be inspected such as an IC. In case where the contact probe 12S for RF signals to be connected to a terminal for RF signals is formed in a coaxial structure, by using a metallic substance such as brass, aluminum, etc. for example, the coaxial structure can be obtained with a small sectional area, by making an inner wall of the insertion hole 11a into which the contact probe 12 for RF signals is inserted as an external conductor, and by making the contact probe 12S for RF signals as a center conductor (an internal conductor). Moreover, in case of the contact probe for signal terminal or power supply terminal (not shown) which is not the contact probe for RF signals, the contact probe is fixed in the insertion hole 11a interposing an insulating tube or the like so as not to come into contact with the metal block 11. In case of the contact probe for grounding, the contact probe 12GND is provided in such a manner that it can be fixed in the insertion hole 11a interposing a conductive GND tube 16 so as to be reliably brought into contact with the metal block 11. Usually, this metal block 11 has a thickness of about 3 to 8 mm, and an area of 30 to 50 mm square.

The contact probe 12 is so constructed that a spring 124 and respective distal ends of plungers (movable pin) 121, 122 are contained in a metal pipe 123, as shown by the sectional explanatory view in FIG. 1C, for example, and the plungers 121, 122 are held so as not to escape from the metal pipe 123 by means of dented parts 123a which are provided in the metal pipe 123, and at the same time, urged outward by the spring 124. When the distal ends of the plungers 121, 122 are pressed, the spring 124 is contracted, and the distal ends are pushed into the metal pipe 123. When a force is not applied, the distal ends of the plungers 121, 122 are projected. A moving amount of the plungers is about 0.3 mm at one side. The probe 120 is designed in such a manner that an appropriate spring pressure can be obtained and reliability is most enhanced, when its total length is reduced by about 0.6 mm by the movements of the two plungers 121, 122 at both upper and lower sides. The metal pipe 123 is formed of nickel silver (an alloy of copper, nickel and zinc), for example, and has a length of about a few millimeters. As the plungers 121, 122, a wire material formed of SK material or beryllium copper and having a diameter of about 0.1 mm is used. The spring 124 is formed of a piano wire or the like.

For the purpose of holding the contact probe 12S for RF signals in the insertion hole 11a concentrically with the insertion hole 11a, keeping a hollow space therein, in the embodiment as shown in FIGS. 1A to 1C, insulating boards 13 are provided on both surfaces of the metal block 11. Each of the insulating boards 13 is provided with recesses 13b corresponding to a shape of an end portion of the metal pipe 123, and through holes 13a which are substantially concentric with the recesses 13b and through which the plungers 121 are passed. This insulating board 13 is fixed to the metal block 11 with small screws, which are not shown, in such a manner that the recesses 13b and the through holes 11a in the metal block 11 are arranged concentrically. In the embodiment as shown in FIGS. 1A to 1C, both ends of the contact probes 12 are held by these insulating boards 13, and the insulating boards 13 are provided on the both surfaces of the metal block 11. However, it is also possible to fix the metal block 11 directly by soldering, without using the contact probes, at a lower end side thereof to be connected to a wiring board which is connected to an inspection device.

The insulating board 13 is preferably formed of resin such as polyether imide (PEI), for example, because the recesses 13b and the through holes 13a can be formed more easily by resin molding at accurate sizes, even in case where a number of the contact probes 12 are arranged in parallel at a narrow pitch. Moreover, the above described resin has a large mechanical strength, and therefore, in case where the insulating board 13 has a thickness of about 1 mm, the insulating board 13 will not be deflected and can stably hold the contact probes even in case where several hundreds or more contact probes are provided. However, any other material may be used, provided that the material is electrically insulating, thin, and has a sufficient mechanical strength.

According to an aspect of the invention, GND posts 14 and/or GND walls 15 (See FIGS. 3A to 3C) are formed in the insulating board 13 at either position surrounding the contact probe 12S for RF signals. Each of the GND posts 14 can be formed by making a through hole in the insulating board 13 in advance, and by pouring metallic material into the through hole, by inserting a metal bar, or by providing a metallic coating on an inner wall of the through hole by plating or by vacuum evaporation. This through hole can be formed in the same manner as the through hole 13a for securing the metal pipe 123 by passing the plunger 121 of the contact probe 12 therethrough, and the recess 13b, which have been described above. In case where the insulating board 13 is formed by resin molding, as described above, it is possible to form the through hole for the GND post 14 too at the same time, and hence, the GND post 14 can be formed very easily.

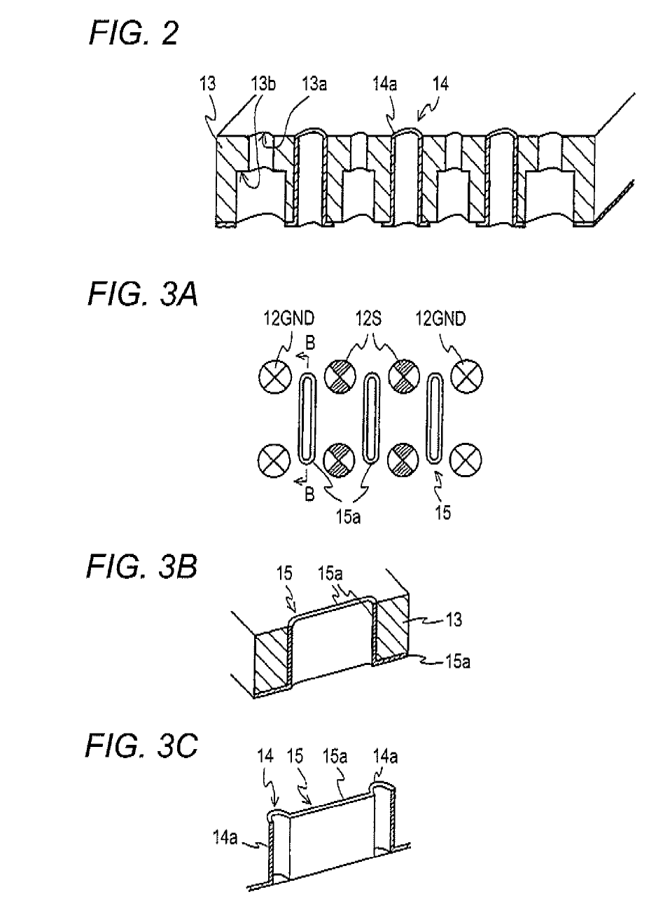

The GND post 14 is shown in a sectional explanatory view partly including a perspective view in FIG. 2, for example, together with the through hole 13a for the contact probe 12 and the recess 13b of the insulating board 13. In the embodiment as shown in FIGS. 1A, 18 and 2, the through hole is formed in the insulating board 13, and a metallic coating 19a is formed on an inner face of the through hole by electroless plating. Although the metallic material is not completely embedded in the through hole in the embodiment, it is possible to form the metallic coating so as to be completely embedded, or to insert the metal bar (a metal pin) instead of forming the metallic coating. However, the metallic material in this through hole must be reliably brought into electrical contact with the metal block 11, and so, in case of forming the metallic coating 19a by plating or by vacuum evaporation, it would be preferable that the metallic coating 19a is continuously formed also on a contact face of the insulating board with respect to the metal block 11, as shown in FIGS. 1B and 2. In this case, it is possible to form the metallic coating 14a so as to be in contact with the recess 13b of the adjacent contact probe 12, in case where the contact probe 12 is the contact probe 12GND for grounding. However, in case where the contact probe 12 is the contact probe 129 for signals or the contact probe for power supply, it would be preferable that the metallic coating 14a is so formed as to keep a space from the recess 13b. This is because it is necessary to prevent the contact probe 12 from being short-circuited with the metal block 11.

In case of forming the metallic coating 14a by electroless plating or vacuum evaporation, a resist film is formed on other areas of the insulating board 13 than an area where the metallic coating 14a is to be formed, and then, the insulating board 13 is soaked in a plating solution, for example, to conduct Ni plating. In order to enhance electrical contact with the metal block 11, it would be preferable to further apply Au or Ag to a surface of the metallic coating 14a by plating. In case where the pitch of the electrode terminals, that is, the pitch of the contact probes 12 on the above described IC is 0.5 mm or less, a diameter of the through hole for forming the GNU post 14 is 0.15 to 0.25 mm, for example, and therefore, it is difficult for the through hole to be impregnated with the plating solution. In such case, it is possible to form the metallic coating on the inner face by vacuum drawing or by agitating the plating solution with ultrasonic waves. Alternatively, the metallic coating may be formed by adhering desired metallic material by vacuum evaporation or spattering, instead of plating. In this case too, a mask is provided in advance on the area where the metallic coating is not formed. In this case, it does not matter that the through hole is completely filled with the metallic material. Moreover, it is also possible to employ such a method that the metallic coating is once formed by plating on an entire surface, without forming the resist film in advance, and thereafter, the metallic coating is scraped of from the area where the metallic coating is not required (by boring with a drill, by scraping with a router, or so).

In case where the contact probes 12 are arranged in a matrix form (arranged in parallel longitudinally and laterally) as shown in FIG. 1A, it would be preferable that the GND post 14 is formed between the contact probes 12 which are adjacent to each other in a diagonal direction, but not between the contact probes 12S for RF signals which are adjacent to each other longitudinally and laterally. This is because a distance between the contact probes 12 which are adjacent to each other in the diagonal direction is the largest. Moreover, for the purpose of easily obtaining advantage of the coaxial structure, it would be preferable that the GND posts 14 surrounding the contact probe 12S for RF signals are at the same distance from the contact probe 12S for RF signals. It would be sufficient that the GND posts 14 are formed around the contact probe 12S for RF signals. In case where the other contact probes for low frequency signals or power supply, or the contact probes 12GND for grounding only are arranged in parallel with each other longitudinally and laterally, it is unnecessary to provide the GND post 14.

In the above described embodiment, the metallic coating is formed in the through hole which is provided in the insulating board 13. However, the GND post 14 is not limited to such structure, but the metallic material may be completely embedded in the through hole, or the metal bar or the like may be embedded in the through hole, as described above. Further, the GND post 14 need not be in a cylindrical shape or in a columnar shape, as shown in FIGS. 1B and 2, but may be in any other shape. An example in which a GND wall 15 in a plate-like shape is formed is shown in FIGS. 3A to 3C.

In case of the GND wall 15, as shown in FIG. 3A, for example, it is possible to form the GND wall 15 by forming a through hole in a strip shape between the contact probes 12 around the contact probe 12S for RF signals, and by forming a metallic coating 15a which is substantially the same as described above on an inner face of the through hole. The through hole in an area where this GND wall 15 is formed is shown in FIG. 3B in a sectional view taken along a line B-B in FIG. 3A and partly including a perspective view, in the same manner as in FIG. 2. However, this GND wall 15 too is provided with the metallic coating 15a at a side opposed to the metal block 11, so as to obtain reliable contact with the metal block 11. In this case, the GND wall 15 may have a very small thickness, or may be interrupted, since a space between the contact probes 12 which are longitudinally and laterally arranged is very small. From this point of view, it would be preferable that the two GND posts 14 are formed in the spaces between the contact probes 128 for RF signals and the contact probes 12 which are adjacent thereto in a diagonal direction, as shown in FIG. 1A, and the GND wall 15 is formed so as to interconnect the GND posts 14, as shown in FIG. 3C. In this manner, effects of the GND posts 14 are further enhanced, even though the GND wall 15 between the GND posts 14 becomes thin or interrupted.

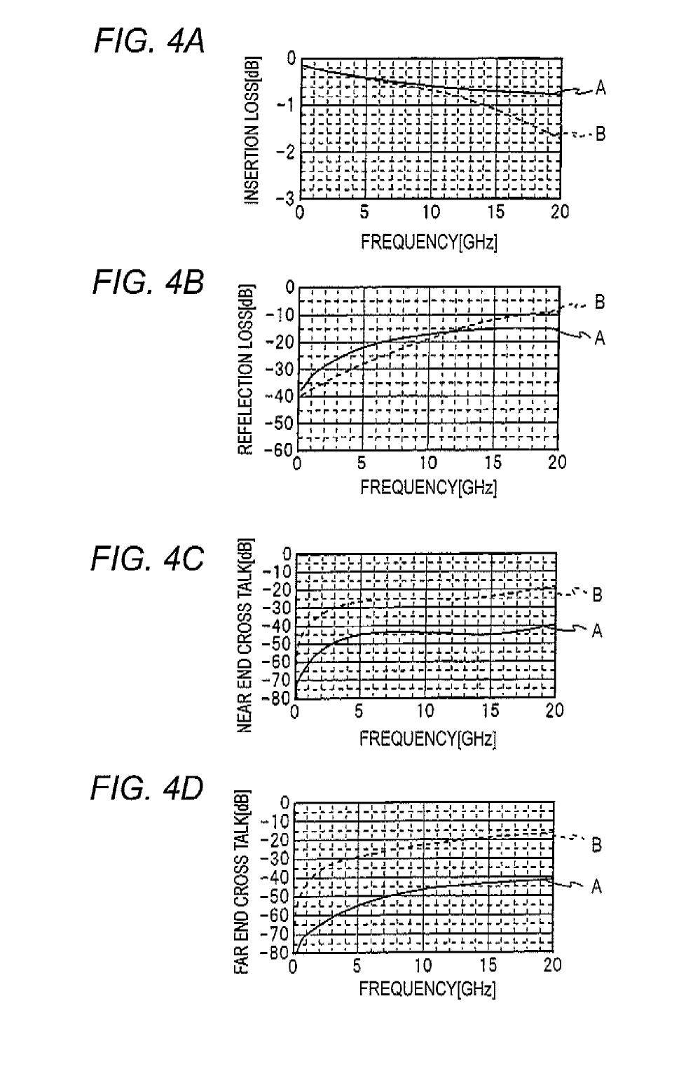

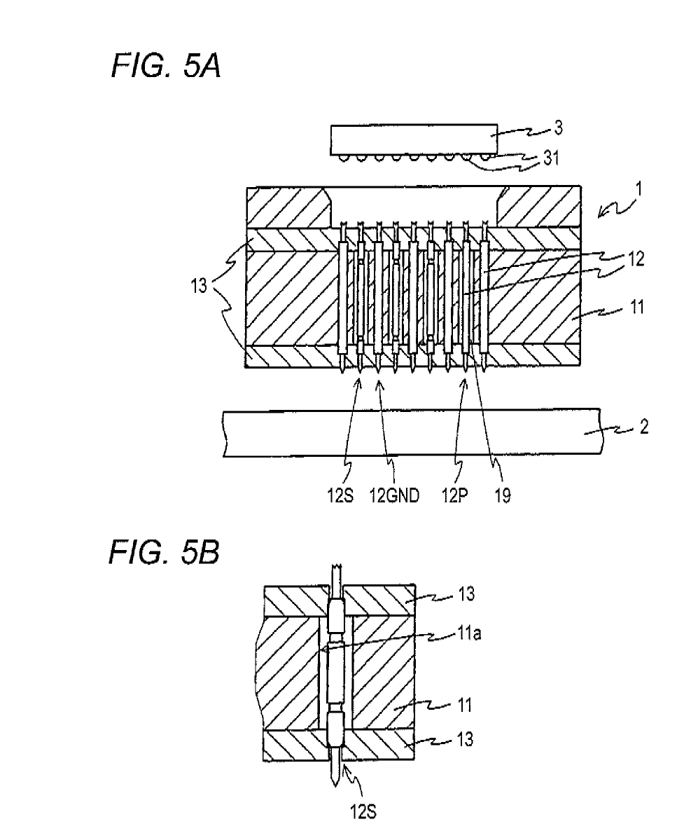

Simulations were carried out using an electromagnetic field analyzing software on both the structure of the invention in which the four contact probes 12S for RF signals and the twelve contact probes 12GND for grounding surrounding the contact probes 128 are arranged, and the GND posts 14 are formed around the contact probes 123 in the diagonal direction, as shown in FIG. 1A, and the related-art structure in which the contact probes are arranged in the same manner as in FIG. 1A, but the GND post 14 is not at all provided. Then, their insertion losses, reflection losses, near end cross talks, and far end cross talks are respectively checked. The results are shown in FIGS. 4A to 4D, in which A represents the case where the socket according to the invention is used, and B represents the case where a socket having the related-art structure without forming the GND post 14 is used.

To begin with, as apparent from FIG. 4A, the insertion loss of the structure A according to the invention becomes smaller at high frequency and high speed over 10 GHz, and an improvement is observed. Moreover, as shown in FIG. 4B, although the reflection loss of the related-art structure B shows better characteristic in a frequency zone up to 12 GHz or so, the reflection loss is increased as compared with the structure A according to the invention, when the frequency exceeds 12 GHz. Generally, it is considered that the socket can be used, in case where the reflection loss is below −10 dB, and the related-art structure cannot be used in a higher frequency zone than 17 GHz or so. In contrast, the structure A according to the invention can be used in the frequency zone over 20 GHz. Further, as shown in FIGS. 4C and 4D, characteristics of the near end cross talk and the far end cross talk are respectively improved by about 18 dB to 25 dB, in an entire frequency zone from DC to 20 GHz, according to the structure of the invention.

As described above, in case of inspecting the IC which has the RF signal terminals, but in which the electrode terminals are arranged at a narrow pitch, the contact probe for RF signals has been held in a hollow space using the metal block so as to obtain the coaxial structure. In the related-art structure, the insulating boards 13 for holding the contact probe 12S in the hollow space have been provided on the upper face and/or the lower face of the metal block 11, and the area of the insulating board 13 has been unable to be formed as the coaxial structure. However, according to the invention, the GND post 14 and/or the GND wall 15 is provided around the contact probe 12S for RF signals on the insulating board 13, and therefore, almost entire area surrounding the contact probe 12S for RF signals can be covered, although such a coaxial structure that the area surrounding the contact probe 12S for RF signals is completely covered with the external conductor cannot be attained. As the results, substantially the same effects as the coaxial structure can be attained. Specifically, the characteristics of the insertion loss and the reflection loss are remarkably improved particularly in the frequency zone over 10 to 20 GHz, and the characteristics of the cross talks are remarkably improved in the entire frequency zone.

Herein, the contact probe means a probe in which a distal end of a lead wire (plunger) is movable, for example, in such a manner that the lead wire (plunger) is provided in a metal pipe by way of a spring so that one end of the plunger may be projected from the metal pipe, while the other end may not escape from the metal pipe, whereby when the one end of the plunger is pressed, the plunger is retracted to an end of the metal pipe, and when an outer force is released, the plunger is projected outward by a force of the spring. Moreover, the RF includes both high frequency in analogue form and high speed of very short pulse width and short pulse interval in digital form, and means a sign wave or a pulse having repetition of more than 1 GHz or so. Further, the object to be inspected means a device including a monolithic IC, a hybrid IC of an LSI (a large scale integrated circuit), or a module component obtained by combining discrete components such as a plurality of ICs and LCRS into hybrid thereby to realize desired functions. Still further, the GND post or GND wall means a post or a wall having such a structure that a metallic coating is formed on an inner wall of a through hole or a strip-shaped hole which is provided in the insulating board, or metallic material is filled in the hole, and the metallic coating or the metallic material is electrically connected to the metal block to be earthed.

Because the GND post or the GND wall is formed by forming the metallic coating on the inner face of the hole which is provided in the insulating board, a cylindrical body or a columnar body provided with the metallic coating at least on the inner face can be obtained, only by applying electroless plating, vacuum evaporation, or spattering to the insulating board which is provided with the hole in advance. Therefore, the GND post or the GND wall can be very easily formed. Moreover, in case where the metallic coating is formed around the hole too by plating or so, on a face of the insulating board at a side to come into contact with the metal block, it is possible to reliably bring the GND post in electrical contact with the metal block. Alternatively, it is also possible to insert a metal bar into the hole, without forming a coating by plating.

In case where the contact probes are arranged in parallel longitudinally and laterally in a plan view, and the GND post is formed between one of the contact probes for RF signals and the contact probe which is adjacent to the contact probe for RF signals in a diagonal direction, the GND post can fully exert a function as the earth with respect to the contact probe for RF signals, while a space for providing the GND post is secured, even though the interval between the contact probes has become very small along with the recent narrow pitch of the electrode terminals of the object to be inspected.

In case where the contact probes are arranged in parallel longitudinally and laterally in a plan view, the GND wall may be formed between one of the contact probes for RF signals and at least one of the contact probes which is longitudinally or laterally adjacent to the contact probe for RF signals or may be formed so as to interconnect two adjacent GND posts which are respectively formed between the contact probes for RF signals and the contact probes which are adjacent to the contact probes for RF signals in a diagonal direction.

It would be preferable that the metallic material for forming the GND posts and GND walls are continuously provided up to a contact face between the insulating board and the metal block, because the electrical connection between the GND post or the GND wall and the metal block can be reliably achieved.

According to an aspect of the invention, in the insulating board for holding the contact probe for RF signals at the center of the insertion hole in the metal block, the GND post or the GND wall can be formed only around the contact probe for RF signals. As the results, it is possible to easily form the GND post or the GND wall only by adding a step for forming the coating by plating or so, or a step for inserting the metal bar, and at the same time, the area of the insulating board for fixing the contact probe can be also formed substantially in the coaxial structure. Specifically, although the external conductor is not completely present around the contact probe for RF signals in the area of the insulating board, by providing the GND posts at four corners in a diagonal direction of the contact probe for RF signals (a diagonal direction of the contact probes which are arranged longitudinally and laterally), for example, the very thin contact probe having an outer diameter of about 0.15 mm can be substantially covered with the GND posts which are provided at the four corners. As the results, an entirety of the contact probe for RF signals can be formed substantially in the coaxial structure, and the RF performance even at more than 10 GHz can be remarkably enhanced.

The inspection socket according to the invention can be utilized for accurately inspecting electrical performance of the object to be inspected in which the electrode terminals are arranged at a very narrow pitch, such as a monolithic IC, a hybrid IC, a module component in which required functions are realized, in an LSI (a large scale integrated circuit) or the like.

What is claimed is:

1. An inspection socket, connecting electrode terminals of an object to be inspected to wirings of a wiring board, the inspection socket comprising:
a metal block formed with first holes;
contact probes provided in the first holes and including at least a contact probe for RF signals, the contact probes provided with plungers capable of moving in an axial direction at distal ends of the contact probes; and
an insulating board securing the contact probes and formed with second holes through which the plungers are passed, the insulating board provided with a GND member around the contact probe for RF signals.

2. The inspection socket according to claim 1, wherein the GND member is defined by a third hole formed in the insulating board and a metallic coating formed on an inner face of the third hole.

3. The inspection socket according to claim 1, wherein the GND member includes a metallic material being in contact with the metal block.

4. The inspection socket according to claim 1, wherein
the contact probes are arranged in a first direction and a second direction perpendicular to the first direction, and
the GND member includes a GND post arranged between the contact probe for RF signals and another contact probe which is diagonally adjacent to the contact probe for RF signals.

5. The inspection socket according to claim 1, wherein
the contact probes are arranged in a first direction and a second direction perpendicular to the first direction, and
the GND member includes a GND wall arranged between the contact probe for RF signals and another contact probe which is adjacent to the contact probe for RF signals in the first direction.

6. The inspection socket according to claim 1, wherein
the contact probes are arranged in a first direction and a second direction perpendicular to the first direction,
the GND member includes GND posts and a GND wall,
the GND posts are arranged in the first direction and are arranged between the contact probe for RF signals and another contact probes which are diagonally adjacent to the contact probe for RF signals, and
the GND wall interconnects the GND posts.
